(19) United States
(12) Patent Application Publication
(10) Pub. No.: US 2025/0329990 A1
(43) Pub. Date: Oct. 23, 2025

(54) LASER ELEMENT AND ELECTRONIC DEVICE

(71) Applicant: SONY GROUP CORPORATION, TOKYO (JP)

(72) Inventor: GEN YONEZAWA, TOKYO (JP)

(21) Appl. No.: 18/849,940

(22) PCT Filed: Mar. 30, 2022
(86) PCT No.: PCT/JP2022/016104

§ 371 Date: Sep. 23, 2024

(51) Int. Cl. H01S 5/40; H01S 5/183

(52) U.S. Cl. CPC H01S 5/4012; H01S 5/18361

(57) ABSTRACT

[Problem] An excitation light output is improved without generating heat and lowering an operational life. [Solution] A laser element includes: a laminated semiconductor layer that includes a first reflection layer used for light of a first wavelength and an active layer that performs surface light emission at the first wavelength; a second reflection layer that is disposed closer to a light emission surface side than the laminated semiconductor layer, and is used for the light of the first wavelength; and a polarization splitting element that individually resonates and multiplexes each of orthogonal polarized beams included in light emitted from the laminated semiconductor layer between the first reflection layer and the second reflection layer.

### TECHNICAL FIELD

The present disclosure relates to a laser element and an electronic device.

### BACKGROUND ART

A laser technique is applied to various fields such as microfabrication, medical devices, or distance measurement. Application of a short pulse laser technique in particular to a highly accurate machining technique or a highly efficient wavelength conversion technique is expected. A Q switch solid state laser among these techniques can obtain high peak power that exceeds kilowatt (kW) with a relatively simple configuration, and therefore is used in a wide application field (see PTL 1).

### CITATION LIST

### Patent Literature

### [PTL 1]

WO 2021/106757 A1

### SUMMARY

### Technical Problem

There has been proposed a multi-junction structure that is provided with a plurality of active layers inside an excitation light source including a laminated semiconductor layer. The excitation light source of this type has higher thermal resistance than that of an Edge Emitting Laser (EEL), and has an upper limit (rollover point) of a light output. Hence, when power of the excitation light source is increased to increase the light output, a junction temperature rises, and a Mean Time to Failure (MTTF) of an element lowers.

PTL 1 discloses a structure obtained by combining the laminated semiconductor layers with a solid state laser medium for a Q switch. A first resonator constituted by the laminated semiconductor layer that is the excitation light source, and the solid state laser medium, and a second resonator constituted by a solid state laser medium and a saturable absorber are adjacent, so that it is possible to excite the solid state laser medium with a high intensity in the first resonator.

It is possible to increase an average output of Q switch light by performing spatial multiplexing using an optical lens or performing multiplexing using polarization. However, the waveform of the Q switch light oscillated by an excitation light emitting source includes jitters, and, even when the waveform is multiplexed, it is not possible to improve total peak power. On the other hand, even when the light output of the excitation light emitting source is increased, an upper limit of a peak intensity of the Q switch light is determined due to a limit of an excitation light output for the above-described reason.

Therefore, the present disclosure provides a laser element and an electronic device that can improve an excitation light output without generating heat and lowering an operational life.

### Solution to Problem

To solve the above problem, the present disclosure provides a laser element that includes: a laminated semiconductor layer that includes a first reflection layer used for light of a first wavelength and an active layer that performs surface light emission at the first wavelength;
a second reflection layer that is disposed closer to a light emission surface side than the laminated semiconductor layer, and is used for the light of the first wavelength; and
a polarization splitting element that individually resonates and multiplexes each of orthogonal polarized beams included in light emitted from the laminated semiconductor layer between the first reflection layer and the second reflection layer.

The laminated semiconductor layer may include a plurality of laminated semiconductor regions associated with the orthogonal polarized beams, and the polarization splitting element may individually resonate and multiplex a corresponding polarized beam between the first reflection layer and the second reflection layer for each of the plurality of laminated semiconductor regions.

The polarization splitting element may include a first surface that is in contact with a light emission surface of the laminated semiconductor layer, and a second surface that is disposed on an opposite side to the first surface and between the first reflection layer and the second reflection layer.

The orthogonal polarized beams may include orthogonal polarized beams of different wavelengths, and
the polarization splitting element may individually resonate and multiplex each of the orthogonal polarized beams including the orthogonal polarized beams of the different wavelengths between the first reflection layer and the second reflection layer.

The orthogonal polarized beams may include a Transverse Magnetic (TM) polarized beam and a Transverse Electric (TE) polarized beam, and
the polarization splitting element may individually resonate and multiplex each of the TE polarized beam and the TM polarized beam between the first reflection layer and the second reflection layer.

The polarization splitting element may multiplex the TE polarized beam with the TM polarized beam inside the polarization splitting element.

The polarization splitting element may include a laminated body obtained by alternately laminating a plurality of polarization splitting films and a plurality of reflection films with an interval spaced apart from each other,
the laminated body may have a cross-sectional surface obtained by cutting the laminated body in a direction of 45 degrees in a normal direction of a lamination surface, and
the polarization splitting element may be disposed such that the normal direction of the cross-sectional surface is parallel to a normal direction of the laminated semiconductor layer.

The polarization splitting element may include a birefringent material for splitting the light emitted from the laminated semiconductor layer into the orthogonal polarized beams.

The laser element may include a laser medium that is disposed closer to the light emission surface side than the polarization splitting element, and resonates at a second wavelength different from the first wavelength.

The laser element may include: a third reflection layer that is disposed on a first end surface of the laser medium on a side of the polarization splitting element, and is used for light of the second wavelength; and
a fourth reflection layer that is disposed on a second end surface of the laser medium on a side opposite to the first end surface, and is used for the light of the second wavelength.

The third reflection layer may be disposed closer to the light emission surface side than the second reflection layer.

The third reflection layer may be disposed between the polarization splitting element and the second reflection layer.

The third reflection layer may be in contact with an end surface of the polarization splitting element.

The fourth reflection layer may be in contact with the second reflection layer or disposed closer to the light emission surface side than the second reflection layer.

The laser element may include a saturable absorber that is disposed closer to the light emission surface side than the laser medium.

The laser element may include: a third reflection layer that is disposed on an end surface of the laser medium on a side facing the polarization splitting element, and is used for light of the second wavelength; and
a fourth reflection layer that is disposed on the light emission surface side of the saturable absorber, and is used for the light of the second wavelength.

The third reflection layer may be disposed closer to the light emission surface side than the second reflection layer.

The second reflection layer may be disposed between the third reflection layer and the fourth reflection layer.

Each of the laminated semiconductor layer, the polarization splitting element, the laser medium, and the saturable absorber may be divided into a plurality of regions in association with a plurality of light emitting units that emit pulse laser light of the second wavelength disposed at a predetermined interval.

The present disclosure provides an electronic device that includes: a laser element; and
a control unit that performs control to emit light from the laser element, and the laser element includes
a laminated semiconductor layer that includes a first reflection layer used for light of a first wavelength and an active layer that performs surface light emission at the first wavelength,
a second reflection layer that is disposed closer to a light emission surface side than the laminated semiconductor layer, and is used for the light of the first wavelength, and
a polarization splitting element that individually resonates and multiplexes each of a plurality of polarized beams included in light emitted from the laminated semiconductor layer between the first reflection layer and the second reflection layer.

### BRIEF DESCRIPTION OF DRAWING

FIG. 1 is a schematic cross-sectional view of a laser element according to a first embodiment.

FIG. 2 is a schematic cross-sectional view of a laser element and a plan view seen from a light emission surface side according to a comparative example.

FIG. 3 is a diagram illustrating a relationship between a current of an excitation light source and a light output in the laser element in FIG. 2.

FIG. 4 is a schematic cross-sectional view of the laser element according to a second embodiment.

FIG. 5 is a view schematically illustrating a manufacturing method for a polarization splitting element.

FIG. 6A is a diagram illustrating an example where a TM polarized beam and a TE polarized beam are multiplexed at a substantially center in a thickness direction of the polarization splitting element.

FIG. 6B is a diagram illustrating an example where the TM polarized beam and the TE polarized beam are multiplexed at a portion shifted from the center in the thickness direction of the polarization splitting element.

FIG. 7 is a schematic cross-sectional view of the laser element according to a third embodiment.

FIG. 8 is a diagram illustrating a design example of a polarization splitting film.

FIG. 9 is a schematic cross-sectional view of the laser element according to a fourth embodiment.

FIG. 10 is a schematic cross-sectional view of the laser element according to a fifth embodiment.

FIG. 11 is a schematic cross-sectional view of the laser element according to a sixth embodiment.

FIG. 12 is a schematic cross-sectional view of the laser element according to a seventh embodiment.

FIG. 13 is a schematic cross-sectional view of the laser element according to an eighth embodiment.

FIG. 14 is a schematic cross-sectional view illustrating respective layers of the laser element in FIG. 13 in more detail.

FIG. 15 is a plan view and a cross-sectional view illustrating a plurality of laser elements disposed in an array.

FIG. 16A is a cross-sectional view of a laser amplification element according to the present disclosure.

FIG. 16B is a perspective view of the laser amplification element according to the present disclosure.

FIG. 17 is a diagram illustrating an example of a schematic configuration of an endoscopic system.

FIG. 18 is a block diagram illustrating an example of a functional configuration of a camera and a CCU illustrated in FIG. 20.

FIG. 19 is a diagram illustrating an example of a schematic configuration of a microsurgery system.

### DESCRIPTION OF EMBODIMENT

Hereinafter, embodiments of a laser element and an electronic device will be described with reference to the drawings. Although main components of the laser element and the electronic device will be mainly described below, the laser element and the electronic device may include components and functions that are not illustrated or explained. The following description does not exclude components or functions that are not illustrated or described.

### First Embodiment

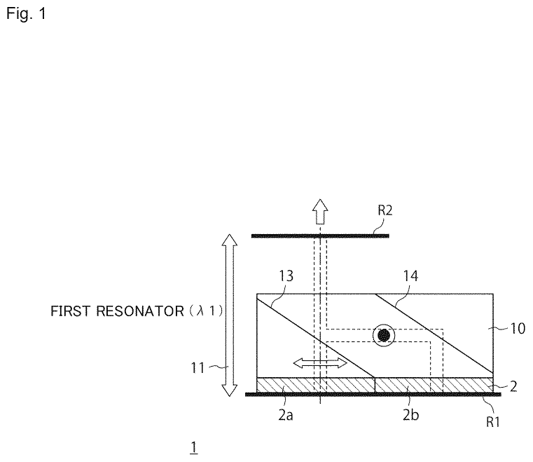

FIG. 1 is a schematic cross-sectional view of a laser element 1 according to the first embodiment. As illustrated in FIG. 1, the laser element 1 according to the first embodiment includes an excitation light source 2 that includes a first reflection layer R1 and an active layer, a second reflection layer R2, and a polarization splitting element 10.

The laser element 1 according to the first embodiment has an integrated laminated structure that can be made using a semiconductor process technique, and consequently has good mass productivity as well as stability of a laser output.

The excitation light source 2 is the laminated semiconductor layer. The excitation light source 2 is referred to as the laminated semiconductor layer 2 below. The laminated semiconductor layer 2 is one form of a surface emitting laser (VCSEL: Vertical Cavity Surface Emitting Laser). What is different from the VCSEL is that the second reflection layer R2 that is at least one of mirrors that constitute a resonator is provided outside the laminated semiconductor layer 2 that is a main body of the excitation light source 2. The second reflection layer R2 is, for example, an external resonator mirror. The laminated semiconductor layer 2 is also referred to as a Vertical External-Cavity Surface Emitting Laser (VECSEL).

The laminated semiconductor layer 2 includes the first reflection layer R1 that is used for light of a first wavelength λ1, and the active layer that performs surface light emission at the first wavelength λ1. A detailed layer configuration of the laminated semiconductor layer 2 will be described later. The second reflection layer R2 is disposed closer to a light emission surface side than the laminated semiconductor layer 2. The first reflection layer R1 and the second reflection layer R2 constitute a first resonator 11 that resonates light of the first wavelength λ1.

The polarization splitting element 10 is an element of a flat plate shape that is provided between the first resonator 11 and polarizes and splits light from the excitation light source 2. The polarization splitting element 10 multiplexes orthogonal polarized beams while uniquely determining a polarization direction. That is, the polarization splitting element 10 individually resonates and multiplexes between the first reflection layer R1 and the second reflection layer R2 each of the orthogonal polarized beams included in light emitted from the laminated semiconductor layer 2 that constitutes the excitation light source 2. The internal structure of the polarization splitting element 10 does not matter. One specific example of the polarization splitting element 10 is a Polarizing Beam Splitter (PBS). For example, the inside of the polarization splitting element 10 is provided with a first optical member 13 that allows a first polarized beam to transmit and reflects a second polarized beam, and a second optical member 14 that reflects the second polarized beam such that the first polarized beam transmits through the first optical member 13 and performs a resonating operation between the first reflection layer R1 and the second reflection layer R2, and the second polarized beam is reflected by the second optical member 14 and the first optical member 13, and performs a resonating operation between the first reflection layer R1 and the second reflection layer R2.

The polarization splitting element 10 includes a first surface that is in contact with the light emission surface of the laminated semiconductor layer 2, and a second layer that is disposed on a side opposite to the first surface and between the first reflection layer and the second reflection layer.

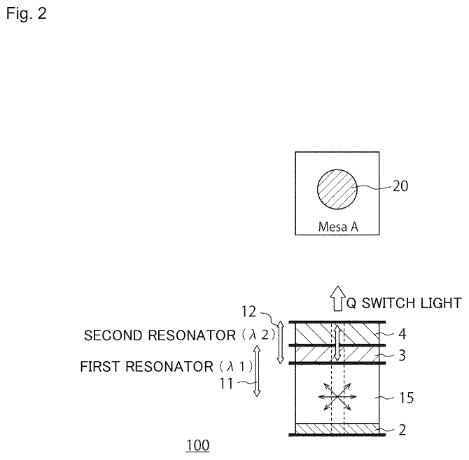

FIG. 2 is a schematic cross-sectional view of a laser element 100 and a plan view seen from a light emission surface side according to a comparative example. The laser element 100 in FIG. 2 employs a configuration where the excitation light source 2 constituted by the laminated semiconductor layer 2, a solid state laser medium 3 for a Q switch, and a saturable absorber 4 are disposed in this order. A uniform material layer 15 that does not control polarization may be disposed between the excitation light source 2 and the solid state laser medium 3. This material layer 15 may be, for example, a support substrate that supports the excitation light source 2.

The laser element 100 in FIG. 2 includes the first resonator 11 that resonates at the first wavelength λ1, and a second resonator 12 that resonates at the second wavelength λ2. The second resonator 12 is also referred to as a Q switch solid state laser resonator. The solid state laser medium 3 in FIG. 2 is used for both of the first resonator 11 and the second resonator 12. The first resonator 11 performs a resonating operation between the excitation light source 2 and the solid state laser medium 3, and the second resonator 12 performs a resonating operation between the solid state laser medium 3 and the saturable absorber 4.

Light of the first wavelength λ1 emitted from the excitation light source 2 and resonated by the first resonator 11 excites the solid state laser medium 3. When power of excitation light of the first wavelength λ1 is accumulated in the solid state laser medium 3, and the solid state laser medium 3 enters a sufficiently excited state, the light absorption rate of the saturable absorber 4 rapidly lowers, the second resonator 12 resonates the light of the second wavelength λ2 between the third reflection layer and the fourth reflection layer, and the saturable absorber 4 emits a Q switch laser pulse. FIG. 2 illustrates an example where the shape of a light emission unit 20 is circular.

The excitation light source 2 in FIG. 2 includes the laminated semiconductor layer 2, and therefore the volume of the active layer in the laminated semiconductor layer 2 is limited. Although there has been also proposed a multi-junction structure that is provided with a plurality of active layers in the laminated semiconductor layer 2, the excitation light source 2 in FIG. 2 has lower thermal conductivity than an edge emitting laser, the active layer has a smaller volume, and therefore a light output cannot be increased. Increasing power of the excitation light source 2 to increase the light output raises a junction temperature, and substantially lowers the operational life of the laser element 1.

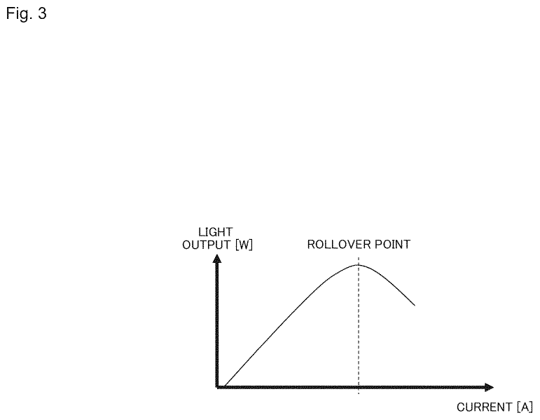

FIG. 3 is a diagram illustrating a relationship between a current of the excitation light source 2 and a light output in the laser element 100 in FIG. 2. When the current to be flown to the excitation light source 2 reaches a predetermined value as illustrated in FIG. 3, the light output reaches an upper limit, and, when the current is further flown, the junction temperature rises and the light output lowers.

Although the light emitted from the excitation light source 2 includes a plurality of polarized beams, the first resonator 11 performs a resonating operation at random irrespectively of types of the polarized beams. Only light energy is transmitted from the first resonator 11 to the second resonator 12 without selecting specific polarization.

By contrast with this, in the laser element 1 according to the first embodiment illustrated in FIG. 1, the laminated semiconductor layer 2 constituting the excitation light source 2 is divided into a plurality of laminated semiconductor regions in association with orthogonal polarized beams included in the light emitted from the excitation light source 2. The plurality of laminated semiconductor regions emit spontaneous emission light of unpolarized beams. The polarization splitting element 10 individually resonates and multiplexes a corresponding polarized beam between the first reflection layer R1 and the second reflection layer R2 for each of the plurality of laminated semiconductor regions.

Consequently, for example, each of the two types of the polarized beams individually performs a resonating operation between the first reflection layer R1 and the second reflection layer R2, so that the laser element 1 in FIG. 1 can substantially double the light output emitted from the polarization splitting element 10 compared to FIG. 2. That the light output emitted from the polarization splitting element 10 can be improved means that, even when the current to be flown to the excitation light source 2 is reduced compared to the laser element 100 in FIG. 2, a high light output can be maintained, and the current to be flown to the excitation light source 2 can be reduced, so that it is possible to increase the operational life of the laser element 1.

The laser element 1 in FIG. 1 can have a bonded integrated structure by the semiconductor process. Consequently, it is possible to improve mass productivity, multiplex excitation light from a plurality of laminated semiconductor regions and increase an excitation light output, and improve the Mean Time to Failure (MTTF) of the laser element 1.

As described above, in the first embodiment, the orthogonal polarized beams included in the light emitted from the laminated semiconductor layer 2 are resonated and multiplexed between the first reflection layer R1 and the second reflection layer R2, so that it is possible to increase the excitation light output without increasing the current to be flown to the excitation light source 2. The excitation light source 2 is, for example, a semiconductor laser. The polarization splitting element 10 is laminated in the first resonator 11 that uses the semiconductor laser, and the polarized beams split in the polarization splitting element 10 are multiplexed, so that even the small laser element 1 can improve the excitation light output. Furthermore, even when the current to be flown to the excitation light source 2 is decreased, it is possible to maintain the high excitation light source, so that it is possible to achieve a longer operational life of the laser element 1.

### Second Embodiment

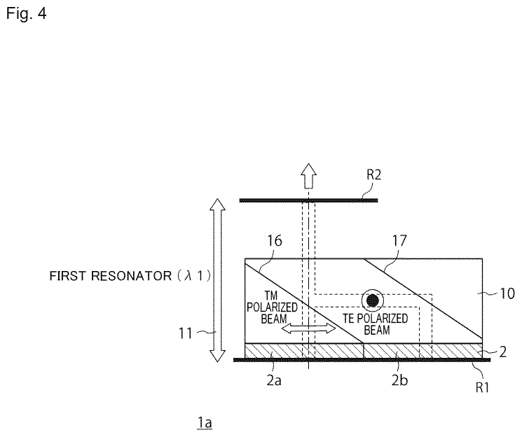

FIG. 4 is a schematic cross-sectional view of a laser element la according to the second embodiment. In the laser element la in FIG. 4, the orthogonal polarized beams included in the light emitted from the laminated semiconductor layer 2 include a Transverse Magnetic (TM) polarized beam and a Transverse Electric (TE) polarized beam. The polarization splitting element 10 individually resonates and multiplexes each of the TE polarized beam and the TM polarized beam between the first reflection layer R1 and the second reflection layer R2.

An example of the polarization splitting element 10 is considered as a polarization conversion element (PS converter). The polarization conversion element can be manufactured by the same manufacturing method as that used generally for a liquid crystal projector. The polarization conversion element for the liquid crystal projector includes an opening window that is disposed on an incidence surface, and a half-wave plate that is disposed on an emission surface. The polarization conversion element according to the present embodiment does not need the opening window and the half-wave plate, and includes a polarization splitting film 16 on a multiplexing surface instead.

The polarization splitting element 10 employs a configuration where the polarization splitting film 16 and a reflection film 17 disposed in a direction inclined at 45 degrees with respect to the normal direction of a light incidence surface are alternately disposed along the light incidence surface. The polarization splitting film 16 has the property that allows the TM polarized beam to transmit, and reflects the TE polarized beam. The reflection film 17 has the property that reflects the TE polarized beam. Hence, the polarization splitting film 16 and the reflection film 17 are adjacently disposed along the light incidence surface such that the TM polarized beam resonates between the first reflection layer R1 and the second reflection layer R2 along the normal direction of the end surface of the polarization splitting element 10. The TE polarized beam resonates between the first reflection layer R1 and the second reflection layer R2 while being reflected by the reflection film 17 and the polarization splitting film 16. The TE polarized beam is reflected by the reflection film 17, and multiplexed with the TM polarized beam when further reflected by the polarization splitting film 16. Consequently, it is possible to increase the excitation light output that is output from the polarization splitting film 16.

Even when a distance between the polarization splitting film 16 and the reflection film 17 is apart one mm or more, the laser element la according to the second embodiment can multiplex the TM polarized beam and the TE polarized beam.

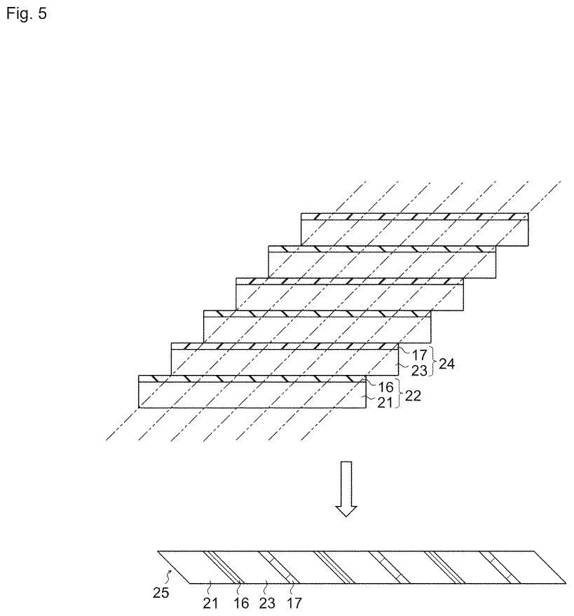

FIG. 5 is a view schematically illustrating a manufacturing method for the polarization splitting element 10. A first substrate 22 including the polarization splitting film 16 formed on the end surface of a base material layer 21, and a second substrate 24 including the reflection film 17 formed on the end surface of a base material layer 23 are alternately laminated to form a laminated body 25. Materials of the base material layers 21 and 23 do not matter in particular, and need to be a material that does not have a polarization splitting function.

Next, the laminated body 25 is cut at an inclination angle of 45 degrees with respect to the normal direction of a substrate surface as indicated by two-dot chain lines in FIG. 5 to make a plurality of polarization splitting elements 10 including a plurality of the laminated bodies 25.

As accuracy of the thicknesses of the individual first substrate 22 and second substrate 24 constituting the laminated body 25 is higher, the optical axes of light to be multiplexed match. Even when a positional shift in a substrate surface direction occurs at a time of bonding, the polarization splitting elements 10 have robustness that does not cause shift of optical paths of the polarization splitting elements 10 to be made.

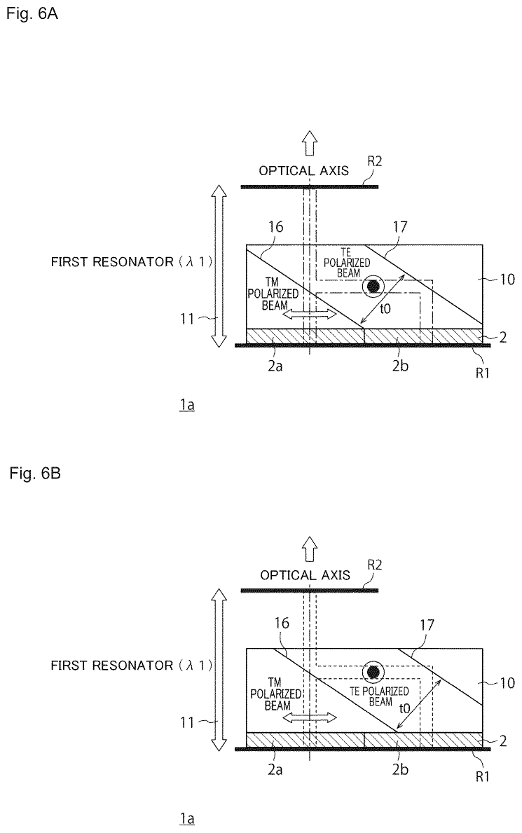

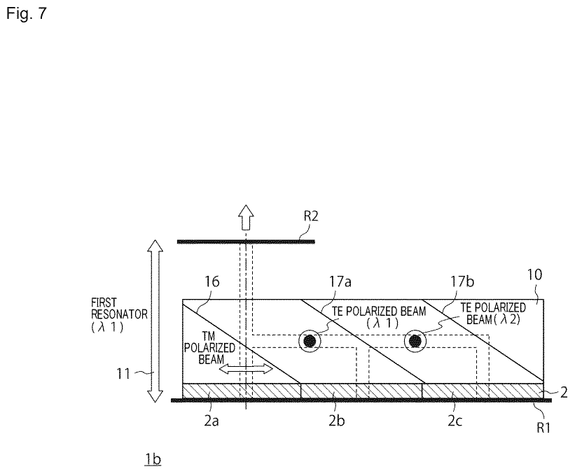

FIG. 6A illustrates an example where the TM polarized beam and the TE polarized beam are multiplexed at a substantially center in a thickness direction of the polarization splitting element 10, and FIG. 6B is a diagram illustrating an example where the TM polarized beam and the TE polarized beam are multiplexed at a portion shifted from the center in the thickness direction of the polarization splitting element 10.

In FIGS. 6A and 6B, although multiplexing positions of the TM polarized beam and the TE polarized beam are different due to a positional shift between the polarization splitting film 16 and the reflection film 17 in the substrate surface direction in the polarization splitting element 10, the optical paths of the multiplexed TM polarized beam and TE polarized beam are not shifted. Consequently, it is possible to improve the robustness.

As described above, according to the second embodiment, by using the polarization splitting element 10 formed by alternately disposing along the light incidence surface the polarization splitting film 16 and the reflection film 17 disposed in the direction inclined at 45 degrees from the normal direction of the substrate surface, it is possible to multiplex inside the polarization splitting element 10 the TM polarized beam and the TE polarized beam included in excitation light, and increase an excitation light output.

### Third Embodiment

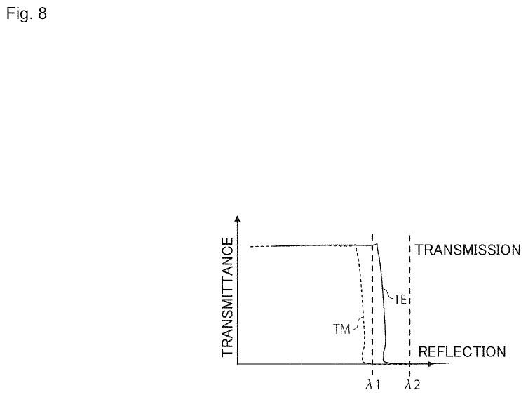

FIG. 7 is a schematic cross-sectional view of a laser element 1b according to the third embodiment. The laser element 1b in FIG. 7 differs from the laser elements 1 and la according to the first and second embodiments in the internal structure of the polarization splitting element 10.

The polarization splitting element 10 according to the third embodiment includes the polarization splitting film 16 and a plurality of reflection films 17a and 17b. The plurality of reflection films 1717a and 17b reflect the TE polarized beams of respectively different wavelengths. The polarization splitting element 10 in FIG. 7 includes the polarization splitting film 16, the first reflection film 17a that reflects the TE polarized beam of the wavelength λ1, and the second reflection film 17b that reflects the TE polarized beam of the wavelength λ2.

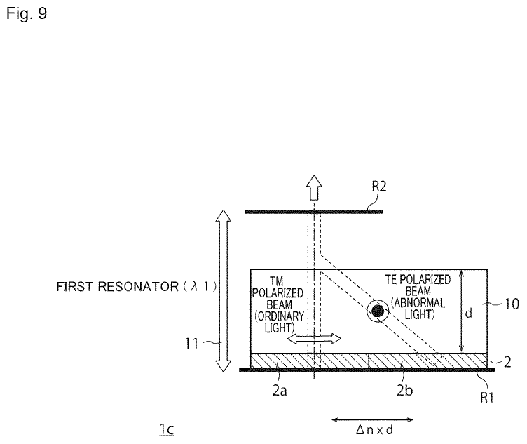

FIG. 8 is a diagram illustrating a design example of the polarization splitting film 16, and the horizontal axis indicates a wavelength and the vertical axis indicates a transmittance. By changing reflection characteristics of the first reflection film 17a and the second reflection film 17b, it is possible to adjust a wavelength band of the excitation light emitted from the polarization splitting element 10, and further improve an output of the excitation light.

### Fourth Embodiment

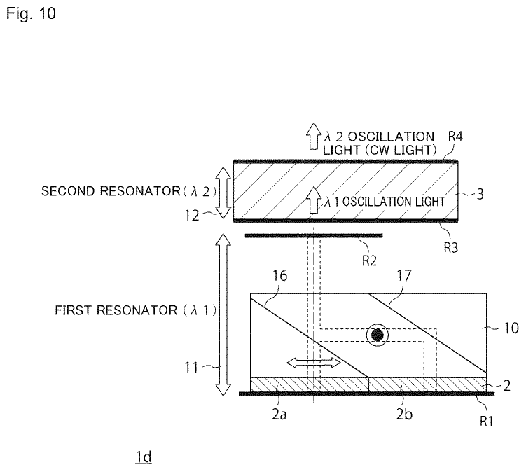

FIG. 9 is a schematic cross-sectional view of a laser element 1c according to the fourth embodiment. While the laser elements la and 1b in FIGS. 4 and 7 include the polarization splitting element 10 formed by alternately disposing the polarization splitting film 16 and the reflection film 17, the laser element 1c in FIG. 9 includes the polarization splitting element 10 made of a birefringent material. The birefringent material is a material that splits incident light into orthogonal polarized beams depending on a polarization state of the incident light. The birefringent material typically splits the incident light into two polarized beams. One of the two polarized beams is referred to as normal light (ordinary light), and the other one is referred to as abnormal light.

FIG. 9 illustrates an example where the TM polarized beam is the normal light, and the TE polarized beam is the abnormal light among the two polarized beams split by the birefringent material. The TM polarized beam performs a resonating operation between the first reflection layer R1 and the second reflection layer R2 along the normal direction of the substrate surface. The TE polarized beam diagonally travels in the birefringent material, is multiplexed with the TM polarized beam, and performs the resonating operation between the first reflection layer R1 and the second reflection layer R2.

Examples of the birefringent material include rutile that is crystal of titanium dioxide (TiO₂), crystal of yttrium vanadate (YVO₄), crystal of lithium niobate (LiNbO₃), crystal, and the like. Note that a specific type of the birefringent material does not matter. A material having high workability such that the transmittance is high with respect to the wavelength of the excitation light emitted from the excitation light source 2, and accuracy in a C axis direction is obtained.

The rutile crystal is a birefringent material that has high birefringence, and a transmitting light beam can be split into ordinary light and abnormal light. A polarization state of the abnormal light is orthogonal to a polarization state of the ordinary light. As for alignment of the excitation light source 2 and the polarization splitting element 10, it is possible to further increase alignment accuracy according to crystal cutting accuracy.

As described above, according to the fourth embodiment, the polarization splitting element 10 is formed using the birefringent material, so that it is possible to simplify the internal structure of the polarization splitting element 10, and simplify the manufacturing process, too. On the other hand, to multiplex the TM polarized beam and the TE polarized beam inside the polarization splitting element 10, it is necessary to optimize the thickness of the polarization splitting element 10 and the birefringent material.

### Fifth Embodiment

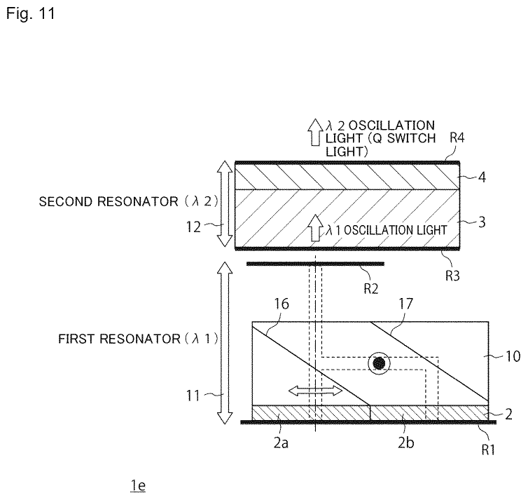

FIG. 10 is a schematic cross-sectional view of a laser element 1d according to the fifth embodiment. The laser element 1d in FIG. 10 employs a configuration where the solid state laser medium 3 is provided to the laser elements 1, 1a, 1b, and 1c according to one of the first to fourth embodiments. The solid state laser medium 3 in FIG. 10 is disposed closer to the light emission surface side than the polarization splitting element 10. For example, the solid state laser medium 3 is disposed closer to the light emission surface side than the second reflection layer R2.

The solid state laser medium 3 resonates at the second wavelength λ2 different from the first wavelength λ1. The solid state laser medium 3 includes a third reflection layer R3 that is disposed on a first end surface, and a fourth reflection layer R4 that is disposed on a second end surface on a side opposite to the first end surface. The third reflection layer R3 and the fourth reflection layer R4 reflect light of the second wavelength λ2. Then, the light of the second wavelength λ2 is resonated between the third reflection layer R3 and the fourth reflection layer R4.

The solid state laser medium 3 contains, for example, Yttrium Aluminum Garnet (YAG) crystal Yb:YAG doped with Ytterbium (Yb). In this case, the first wavelength λ1 of the first resonator 11 is 940 nm, and the second wavelength λ2 of the second resonator 12 is 1030 nm.

The solid state laser medium 3 is not limited to, for example, Yb:YAG, and for example, at least one material of Nd:YAG, Nd:YVO₄, Nd:YLF, Nd:glass, Yb:YAG, Yb:YLF, Yb:FAP, Yb:SFAP, Yb:YVO, Yb:glass, Yb:KYW, Yb:BCBF, Yb:YCOB, Yb:GdCOB, and YB:YAB can be used. The form is not limited to crystal, and does not prevent use of ceramic materials.

Furthermore, the solid state laser medium 3 may be the four-level system solid state laser medium 3, or may be a quasi-three-level system solid laser 3. In this regard, since each crystal has a different appropriate excitation wavelength (first wavelength λ1), it is necessary to select a semiconductor material of the active layer in the excitation light source 2 according to the material of the solid state laser medium 3.

As described above, in the fifth embodiment, the solid state laser medium 3 is disposed closer to the light emission surface side than the polarization splitting element 10, so that it is possible to convert the wavelength of emission light. The laser element 1d according to the fifth embodiment can be also formed by the semiconductor process, so that it is possible to improve mass productivity.

### Sixth Embodiment

A laser element according to the sixth embodiment includes a saturable absorber provided closer to the light emission surface side than the solid state laser medium 3.

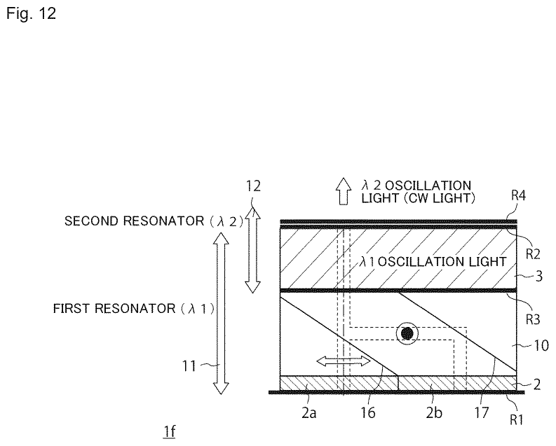

FIG. 11 is a schematic cross-sectional view of a laser element 1e according to the sixth embodiment. The laser element 1e in FIG. 11 employs a configuration where the solid state laser medium 3 and the saturable absorber 4 are provided to the laser elements 1 to 1c according to one of the first to fourth embodiments. The solid state laser medium 3 in FIG. 11 is disposed closer to the light emission surface side than the polarization splitting element 10, and the saturable absorber 4 is disposed closer to the light emission surface side than the solid state laser medium 3.

The solid state laser medium 3 and the saturable absorber 4 resonate at the second wavelength λ2 different from the first wavelength λ1. The end surface of the solid state laser medium 3 on a side facing the polarization splitting element 10 is provided with the third reflection layer R3 used for the light of the second wavelength λ2. The light emission surface side of the saturable absorber 4 is provided with the fourth reflection layer R4 used for the light of the second wavelength λ2. The third reflection layer R3 and the fourth reflection layer R4 reflect the light of the second wavelength λ2. Then, the light of the second wavelength λ2 is resonated between the third reflection layer R3 and the fourth reflection layer R4.

The saturable absorber 4 contains, for example, YAG (Cr:YAG) crystal doped with Cr (chromium). The saturable absorber 4 is a material whose transmittance increases when the intensity of incident light exceeds a predetermined threshold. The excitation light of the first wavelength λ1 from the first resonator 11 increases the transmittance of the saturable absorber 4, and emits a laser pulse of the second wavelength λ2. This is referred to as a Q switch. As the material of the saturable absorber 4, V:YAG can be also used. In this regard, other types of the saturable absorber 4 may be used. Furthermore, an active Q switch element is not prevented from being used as the Q switch.

As described above, in the sixth embodiment, the solid state laser medium 3 and the saturable absorber 4 are disposed in order on the light emission surface side of the polarization splitting element 10, so that it is possible to emit a Q switch pulse without a jitter using excitation light whose light output has been improved by being multiplexed by the polarization splitting element 10.

### Seventh Embodiment

A laser element according to the seventh embodiment shares the solid state laser medium 3 for the first resonator 11 and the second resonator 12.

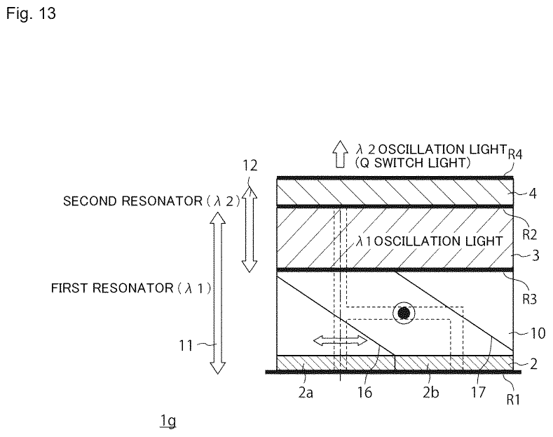

FIG. 12 is a schematic cross-sectional view of a laser element If according to the seventh embodiment. The laser element lf in FIG. 12 includes the solid state laser medium 3 disposed on the light emission surface side of the polarization splitting element 10. The first reflection layer R1 is disposed on an end surface on the side opposite to the light emission surface of the laminated semiconductor layer 2 that is the excitation light source 2. The third reflection layer R3 is disposed between the polarization splitting element 10 and the solid state laser medium 3. The second reflection layer R2 and the fourth reflection layer R4 are disposed on the light emission surface side of the solid state laser medium 3.

The laser element If in FIG. 12 includes the first resonator 11 and the second resonator 12. The first resonator 11 resonates the light of the first wavelength λ1 between the first reflection layer R1 and the second reflection layer R2. The second resonator 12 resonates the light of the second wavelength λ2 between the third reflection layer R3 and the fourth reflection layer R4. Hence, the solid state laser medium 3 is shared between the first resonator 11 and the second resonator 12.

Consequently, by sharing the solid state laser medium 3 between the first resonator 11 and the second resonator 12, it is possible to shorten the resonator length of the laser element 1f, and emit laser light whose pulse width is small and whose laser peak power is high.

### Eighth Embodiment

A laser element according to the eighth embodiment includes the saturable absorber 4 disposed closer to the light emission surface than the solid state laser medium 3 in the laser element If according to the seventh embodiment.

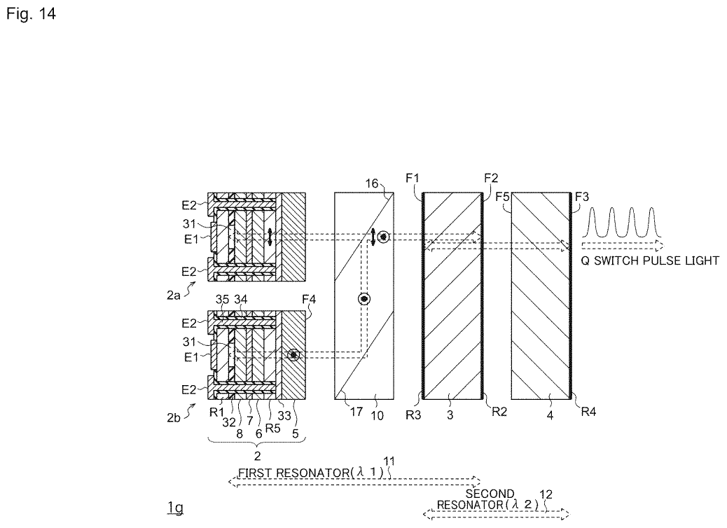

FIG. 13 is a schematic cross-sectional view of a laser element 1g according to the eighth embodiment. The laser element 1g in FIG. 13 employs a configuration where the solid state laser medium 3 and the saturable absorber 4 are disposed in order on the light emission surface side of the polarization splitting element 10. The laser element 1g in FIG. 13 includes the first reflection layer R1 to the fourth reflection layer R4. The first reflection layer R1 is disposed on the end surface on the side opposite to the light emission surface of the laminated semiconductor layer 2 that is the excitation light source 2. The second reflection layer R2 is disposed between the solid state laser medium 3 and the saturable absorber 4. The third reflection layer R3 is disposed between the polarization splitting element 10 and the laser element 1g. The fourth reflection layer R4 is disposed on the light emission surface side of the saturable absorber 4.

The laser element 1g in FIG. 13 includes the first resonator 11 and the second resonator 12. The first resonator 11 resonates the light of the first wavelength λ1 between the first reflection layer R1 and the second reflection layer R2. The second resonator 12 resonates the light of the second wavelength λ2 between the third reflection layer R3 and the fourth reflection layer R4. The solid state laser medium 3 is shared as the first resonator 11 and the second resonator 12.

It is possible to shorten the resonator lengths, so that the laser element 1g in FIG. 13 can emit the Q switch pulse laser light whose pulse width is small, whose laser peak power is high and that has no jitter using excitation light whose light output has been improved by being multiplexed by the polarization splitting element 10.

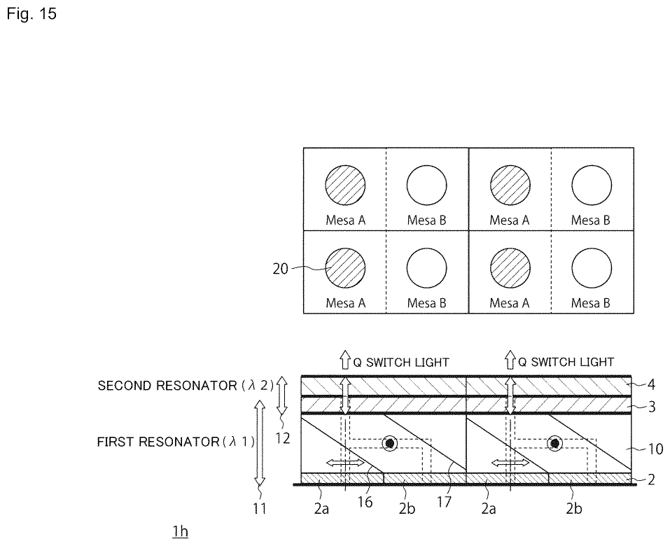

FIG. 14 is a schematic cross-sectional view illustrating respective layers of the laser element 1g in FIG. 13 in more detail. The laminated semiconductor layer 2 that is the excitation light source 2 includes two laminated semiconductor regions. Hereinafter, these two laminated semiconductor regions will be referred to as a first laminated semiconductor region 2a and a second laminated semiconductor region 2b.

The TM polarized beam performs a resonating operation between the first laminated semiconductor region 2a, the polarization splitting element 10, and the solid state laser medium 3. Furthermore, the TE polarized beam emitted from the second laminated semiconductor region 2b and split by the polarization splitting element 10 is multiplexed with the TM polarized beam inside the polarization splitting element 10.

The excitation light source 2 constituted by the laminated semiconductor layer 2 to be divided into the first laminated semiconductor region 2a and the second laminated semiconductor region 2b has a structure that a substrate 5, an n-contact layer 33, a fifth reflection layer R5, a clad layer 6, an active layer 7, a clad layer 8, a pre-oxidation layer 31, and the first reflection layer R1 are laminated in order. Note that the laser element 1g in FIG. 1 employs a configuration of a bottom emission type where the substrate 5 emits excitation light of a Continuous Wave (CW), yet may also employ a configuration of a top emission type where CW excitation light is emitted from a first reflection layer R1 side.

The substrate 5 is, for example, an n-GaAs substrate 5. The n-GaAs substrate 5 absorbs a certain rate of the light of the first wavelength λ1 that is the excitation wavelength of the excitation light source 2, and is desirably made as thin as possible. On the other hand, the n-GaAs substrate 5 desirably has such a thickness that mechanical strength at a time of a bonding process to be described later can be maintained.

The active layer 7 performs surface light emission at the first wavelength λ1. The clad layers 6 and 8 are, for example, AlGaAs clad layers. The first reflection layer R1 reflects the light of the first wavelength λ1. The fifth reflection layer R5 has a certain transmittance with respect to the light of the first wavelength λ1. Distributed Bragg Reflectors (DBRs) that enable electrical conduction are used for the first reflection layer R1 and the fifth reflection layer R5. The current is injected from the outside through the first reflection layer R1 and the fifth reflection layer R5, recombination and light emission occur in a quantum well in the active layer 7, and laser oscillation at the first wavelength λ1 is performed. Part of a pre-oxidation layer (e.g., AlAs layer) 31 on a clad layer side of the first reflection layer R1 is oxidized as a post-oxidation layer (e.g., Al₂O₃ layer) 32.

The fifth reflection layer R5 is disposed on, for example, the n-GaAs substrate 5. For example, the fifth reflection layer R5 includes the multilayer reflection film 17 made of Al_{z1}Ga_{1-z1}As/Al_{z2}Ga_{1-z2}As (0≤z1≤z2≤1) doped with an n-type dopant (e.g., silicon). The fifth reflection layer R5 is also referred to as an n-DBR. In more detail, the n-contact layer 33 is disposed between the fifth reflection layer R5 and the n-GaAs substrate 5.

The active layer 7 includes a multiple quantum well layer formed by laminating, for example, an Alₓ₁In_{y1}Ga_{1-x1-y1}As layer and an Alₓ₃In_{y3}Ga_{1-x3-y3}As layer.

The first reflection layer R1 includes, for example, a multilayer reflection film made of Al_{z3}Ga_{1-z3}As/Al_{z4}Ga_{1-z4}As (0≤z3≤z4≤1) doped with a p-type dopant (e.g., carbon) The first reflection layer R1 is also referred to as a p-DBR.

The semiconductor layers R5, 6, 7, 8, and R1 in the excitation light source 2 can be formed using a crystal growth method such as the Metal Organic Chemical Vapor Deposition (MOCVD) method or the Molecular Beam Epitaxy (MBE) method. Furthermore, it is possible to perform driving by current injection after a process such as mesa etching for element isolation, formation of an insulating film, deposition of an electrode film, and the like after crystal growth.

The solid state laser medium 3 is bonded to the end surface on the side opposite to the fifth reflection layer R5 of the n-GaAs substrate 5 of the excitation light source 2. Hereinafter, the end surface on an excitation light source 2 side of the solid state laser medium 3 will be referred to as a first surface F1, and an end surface on a saturable absorber 4 side of the solid state laser medium 3 will be referred to as a second surface F2. Furthermore, a laser pulse emission surface of the saturable absorber 4 will be referred to as a third surface F3, and an end surface on the solid state laser medium 3 side of the excitation light source 2 will be referred to as a fourth surface F4. Furthermore, an end surface on the solid state laser medium 3 side of the saturable absorber 4 will be referred to as a fifth surface F5. Although separated and illustrated for ease of convenience in FIG. 1, the fourth surface F4 of the excitation light source 2 is bonded to the first surface F1 of the solid state laser medium 3, and the second surface F2 of the solid state laser medium 3 is bonded to the fifth surface F5 of the saturable absorber 4.

The laser element 1 in FIG. 1 includes the first resonator 11 and the second resonator 12. The first resonator 11 resonates the light of the first wavelength λ1 between the first reflection layer R1 in the excitation light source 2 and the second reflection layer R2 in the solid state laser medium 3. The second resonator 12 resonates the light of the second wavelength λ2 between the third reflection layer R3 in the solid state laser medium 3 and the fourth reflection layer R4 in the saturable absorber 4.

The second resonator 12 is also referred to as the Q switch solid state laser resonator 12. The second reflection layer R2 that is a highly reflective layer is provided in the solid state laser medium 3 such that the first resonator 11 can perform a stable resonating operation. The normal excitation light source 2 includes a partial reflection mirror that is disposed at a position of the second reflection layer R2 in FIG. 1 and emits the light of the first wavelength λ1 to the outside. By contrast with this, in the laser element 1 in FIG. 1, the second reflection layer R2 is used as the highly reflective layer to use the second reflection layer R2 to trap power of the excitation light of the first wavelength λ1 in the first resonator 11.

As described above, inside the first resonator 11 including the excitation light source 2 and the solid state laser medium 3, three reflection layers (the first reflection layer R1, the fifth reflection layer R5, and the second reflection layer R2) are provided. Hence, the first resonator 11 has a coupled cavity structure.

By trapping the power of the excitation light of the first wavelength λ1 in the first resonator 11, the solid state laser medium 3 is excited. Consequently, Q switch laser pulse oscillation occurs in the second resonator 12. The second resonator 12 resonates the light of the second wavelength λ2 between the third reflection layer R3 in the solid state laser medium 3 and the fourth reflection layer R4 in the saturable absorber 4. While the third reflection layer R3 is a highly reflective layer, the fourth reflection layer R4 is a partially reflective layer. Although the fourth reflection layer R4 is provided on the end surface of the saturable absorber 4 in FIG. 1, the fourth reflection layer R4 may be disposed closer to an optical axis rear side than the saturable absorber 4. The optical axis rear is an emission direction of light on the optical axis. That is, the fourth reflection layer R4 does not necessarily need to be provided inside or on the front surface of the saturable absorber 4. The fourth reflection layer R4 is an output coupling mirror in the second resonator 12.

Although FIG. 1 illustrates the separated excitation light source 2, solid state laser medium 3, and saturable absorber 4 are separated, these excitation light source 2, solid state laser medium 3, and saturable absorber 4 are a laminated structure that has been integrated by being bonded using the bonding process. As an example of the bonding process, surface activated bonding, atomic diffusion bonding, plasma activation bonding, and the like can be used. Alternatively, other bonding (adhering) processes can be used.

To stably bond the solid state laser medium 3 to the excitation light source 2, it is necessary to make the front surface of the n-GaAs substrate 5 in the excitation light source 2 flat. Hence, as described above, electrodes E1 and E2 for injecting the current to the first reflection layer R1 and the fifth reflection layer R5 are desirably disposed such that at least the front surface of the n-GaAs substrate 5 is not exposed. In the example in FIG. 1, the electrodes E1 and E2 are disposed on the end surface on a first reflection layer R1 side of the excitation light source 2. The electrode E1 is a p electrode, and conducts with the first reflection layer R1. The electrode E2 is an n electrode, and is formed by filling a conductive material 35 in an inner wall of a trench that reaches the n-contact layer 33 from the first reflection layer R1 with an insulating film 34 interposed therebetween. By disposing the electrodes E1 and E2 on the same end surface of the excitation light source 2 as in FIG. 1, it is possible to solder and mount this end surface on an unillustrated support substrate. Even when a plurality of laser elements 1 are disposed in an array, it is possible to achieve a form that enables this end surface on the support substrate by disposing the electrodes E1 and E2 on the same end surface. Note that the shapes and arrangement positions of the electrodes E1 and E2 illustrated in FIG. 1 are merely an example.

As described above, the laser element 1 in FIG. 1 has the laminated structure, so that it is easy to make the laminated structure, and then dice and singulate the laminated structure into a plurality of chips, or form a laser array obtained by disposing in the array the plurality of laser elements 1 on one substrate.

When the laser element 1 of the laminated structure is made by the bonding process, arithmetic mean roughness Ra of each front surface layer needs to be 1 nm degree or less, and is desirably 0.5 nm or less. Chemical Mechanical Polishing (CMP) is used to provide these front surface layers having the arithmetic mean roughness. Furthermore, a dielectric multilayer film may be disposed between the respective layers, and the respective layers may be bonded with the dielectric multilayer films interposed therebetween to avoid light loss at the interface between the respective layers. For example, a refractive index n of the GaAs substrate surface 5 that is a base substrate of the excitation light source 2 with respect to 940 nm in wavelength is 3.5, and is a high refractive index compared to YAG (n:1.8) and general dielectric multilayer film materials. Hence, when the solid state laser medium 3 and the saturable absorber 4 are bonded to the excitation light source 2, it is necessary to prevent light loss due to mismatch of the refractive index. More specifically, an anti-reflection film (an AR coating film or an anti-reflection coating film) that does not reflect the light of the first wavelength λ1 of the first resonator 11 is desirably disposed between the excitation light source 2 and the solid state laser medium 3. Furthermore, the anti-reflection film (the AR coating film or the anti-reflection coating film) is also desirably disposed between the solid state laser medium 3 and the saturable absorber 4.

Polishing is difficult depending on bonding materials, and, for example, a material such as SiO₂ that is transparent for the first wavelength λ1 and the second wavelength λ2 may be formed as an underlayer for bonding, and this SiO₂ layer may be polished to arithmetic mean roughness Ra=approximately 1 nm (desirably 0.5 nm or less), and used as an interface for bonding. Here, other materials than SiO₂ can be used as the underlayer, and are not limited to the materials. Note that an anti-reflection film may be provided between SiO₂ that is the material of the underlayer and the base material layer.

The dielectric multilayer film includes a Short Wave Pass Filter (SWPF), a Long Wave Pass Filter (LWPF), a Band Pass Filter (BPF), an anti-reflection (AR:Anti-Reflection) protective film, and the like, and is a coating layer formed by alternately laminating a high refractive index material layer and a low refractive index material layer. Different types of dielectric multilayer films are desirably disposed as needed. As a method for forming the dielectric multilayer films, the Physical Vapor Deposition (PVD) method can be used, more specifically, film formation methods such as vacuum deposition, ion assisted deposition, and spattering can be used. Which film formation method to apply does not matter. Furthermore, the characteristics of the dielectric multilayer film can be also arbitrarily selected, and, for example, the third reflection layer R3 may be the short wave pass filter and the second reflection layer R2 may be the long wave pass filter. Furthermore, by applying the long wave pass filter to the second reflection layer R2, it is possible to prevent intrusion of the first wavelength λ1 in the saturable absorber 4 and prevent an erroneous operation of the Q switch. Note that short wave pass means to allow the light of the first wavelength λ1 to transmit, and reflect the light of the second wavelength λ2. Furthermore, long wave pass means to reflect the light of the first wavelength λ1, and allows the light of the second wavelength λ2 to transmit.

Furthermore, a diffraction grating may be provided inside the second resonator 12 to convert a polarization state of a laser pulse to be emitted from random polarization into linear polarization. For example, a material such as SiO₂ can be formed as a film, and polished as an interface for bonding at the photonic crystal structure or a fine groove portion of the diffraction grating.

In the laser element 1g in FIG. 14, the current is injected into the active layer 7 via the electrode of the excitation light source 2 to cause laser oscillation of the first wavelength λ1 in the first resonator 11 and excite the solid state laser medium 3. Since the saturable absorber 4 is bonded to the solid state laser medium 3, spontaneous emission light from the solid state laser medium 3 is absorbed by the saturable absorber 4 at an initial stage of occurrence of the laser oscillation of the first wavelength λ1, optical feedback from the fourth reflection layer R4 on an emission surface side of the saturable absorber 4 does not occur, and Q switch laser oscillation does not occur.

Then, when power of excitation light of the first wavelength λ1 is accumulated in the solid state laser medium 3, and the solid state laser medium 3 enters a sufficiently excited state, an output of the spontaneous emission light increases and, when the output exceeds a certain threshold, the light absorption rate of the saturable absorber 4 rapidly lowers, and the spontaneous emission light produced by the solid state laser medium 3 can transmit through the saturable absorber 4. Consequently, the light of the first wavelength λ1 from the first resonator 11 is emitted from the solid state laser medium 3, and the second resonator 12 resonates the light of the second wavelength λ2 between the second reflection layer R2 and the fourth reflection layer R4. Consequently, Q switch laser oscillation occurs, and a Q switch laser pulse is emitted toward a space (a space on the right side in FIG. 1) via the fourth reflection layer R4.

As described above, in the laser element 1g according to the eighth embodiment, the TM polarized beam is multiplexed with the TE polarized beam to obtain a light output inside the polarization splitting element 10, so that it is possible to increase the light output emitted from the polarization splitting element 10. The first resonator 11 resonates the light of the first resonator λ1 between the first reflection layer R1 that is disposed on the end surface on the side opposite to the light emission surfaces of the first laminated semiconductor region 2a and the second laminated semiconductor region 2b, and the second reflection layer R2 between the solid state laser medium 3 and the saturable absorber 4. Furthermore, the second resonator 12 resonates the light of the second wavelength λ2 between the third reflection layer R3 between the polarization splitting element 10 and the solid state laser medium 3, and the fourth reflection layer R4 on the light emission surface side of the saturable absorber 4. By sharing the solid state laser medium 3 between the first resonator 11 and the second resonator 12, it is possible to emit Q switch pulse laser light whose pulse width is small, whose laser peak power is high, and that has no jitter.

### Ninth Embodiment

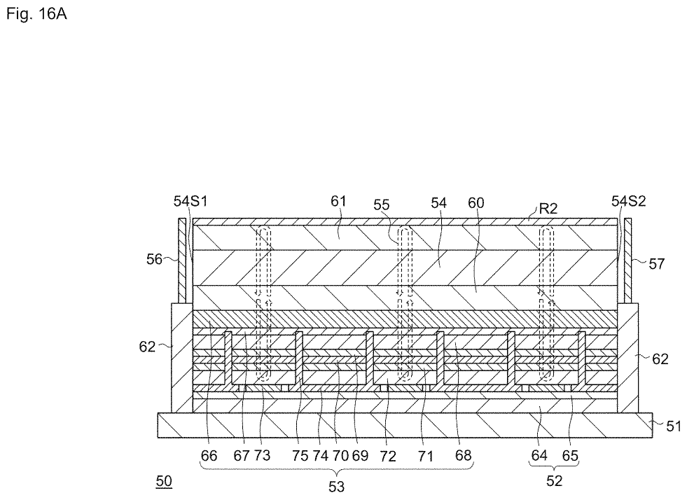

The laser elements 1 to 1g according to the first to eighth embodiments can be disposed in an array. FIG. 15 is a plan view and a cross-sectional view illustrating a plurality of laser elements 1h disposed in an array.

As illustrated in FIG. 15, the laminated semiconductor layer 2 that constitutes the excitation light source 2 is divided into a plurality of the laminated semiconductor regions 2a and 2b. One of the two adjacent laminated semiconductor regions 2a and 2b is used to emit the TM polarized beam, and the other one is used to multiplex the TE polarized beam with the TM polarized beam. Hence, while excitation light is emitted from one Mesa A of two light emission units corresponding to the two adjacent laminated semiconductor regions 2a and 2b, excitation light is hardly emitted from the other Mesa B. Hence, the light emission unit that emits the excitation light may be made larger.

As described above, according to the ninth embodiment, the plurality of laser elements 1h whose light outputs have been increased by providing the polarization splitting element 10 are disposed in the two-dimensional direction, so that it is possible to implement the laser elements 1h that can achieve a high light output and have a longer operational life.

### Tenth Embodiment

It is also possible to make a laser amplification element using the structure of the above-described laser element 1d or If in FIG. 10 or 12.

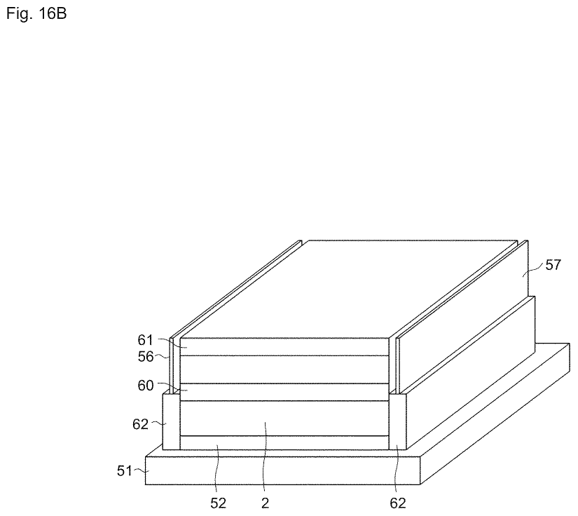

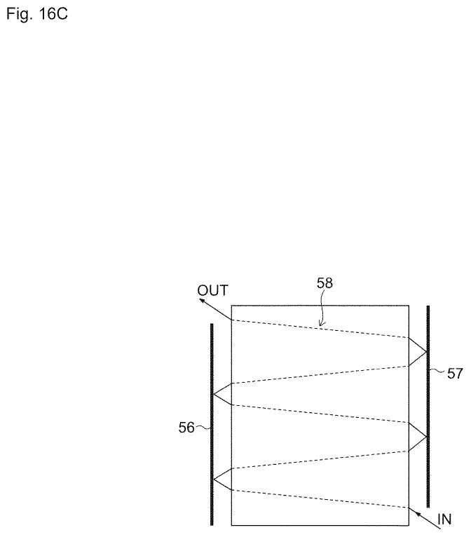

FIG. 16A is a cross-sectional view of a laser amplification element 50 according to the present disclosure, and FIG. 16B is a perspective view of the laser amplification element 50 according to the present disclosure. Furthermore, FIG. 16C is a plan view schematically illustrating an optical path of laser light in the laser amplification element 50.

The laser amplification element 50 in FIGS. 16A to 16C includes an excitation light source 53 that is disposed on a support substrate 51 with a submount substrate 52 interposed therebetween, a polarization splitting element 60 that is disposed on the excitation light source 53, and a solid state laser medium 54 that is disposed on the polarization splitting element 60, and is not provided with the saturable absorber 4. The solid state laser medium 54 is, for example, Yb:YAG. As described later, the excitation light source 53 and the solid state laser medium 54 constitute a first resonator 55, and the light of the first wavelength λ1 is resonated in an upper/lower direction (lamination direction) in FIG. 16A. More specifically, the first resonator 55 resonates the light of the first wavelength λ1 between the first reflection layer R1 (p-DBR 72) in the excitation light source 53 and the second reflection layer R2 in the solid state laser medium 54. Although the solid state laser medium 3 in the laser element 1 in FIG. 1 includes the third reflection layer R3 on the end surface facing the excitation light source 2, and includes the fourth reflection layer R4 on the end surface facing the saturable absorber 4, the solid state laser medium 54 in FIG. 16A does not need the reflection layer on the end surface facing the excitation light source 53, and includes the second reflection layer R2 on the end surface on the side opposite to the reflection layer.

Furthermore, the laser amplification element 50 in FIGS. 16A to 16C includes the first reflection member 56 and the second reflection member 57 that are disposed along an opposing first side surface 54S1 and second side surface 54S2 of the solid state laser medium 54, and the solid state laser medium 54 that functions as an amplification medium 83 that causes the light of the second wavelength λ2 to reciprocate a plurality of times between the first reflection member 56 and the second reflection member 57.

The first reflection member 56 and the second reflection member 57 may include flat reflection mirrors, or may have reflection mirrors of convex shapes to increase the light intensity in a process of amplification and avoid optimal damages on the materials.

Although the first reflection member 56 and the second reflection member 57 are disposed at a distance apart from the first side surface 54S1 and the second side surface 54S2 of the solid state laser medium 54 in FIG. 16A, multilayer films formed by laminating at least one of a semiconductor material, a metal material, and a dielectric material on the first side surface 54S1 and the second side surface 54S2 may be formed, and these multilayer films may be used as the reflection mirrors.

Furthermore, the laser amplification element 50 in FIGS. 16A to 16C includes a light input unit IN that is provided along the first side surface 54S1, and a light output unit OUT that is provided along the second side surface 54S2. The light input unit IN inputs weak light (seed light) of the second wavelength λ2 to the first side surface 54S1. The light of the second wavelength λ2 reciprocates a plurality of times in the amplification medium 83, and is emitted from the light output unit OUT.

Furthermore, the laser amplification element 50 according to the present embodiment includes the polarization splitting element 60 similar to the polarization splitting element 10 according to the first to ninth embodiments. By providing the polarization splitting element 60, it is possible to increase the light output emitted from the polarization splitting element 10.

Furthermore, the laser amplification element 50 in FIGS. 16A to 16C may include a cooling member 62. The cooling member 62 is bonded to the side surfaces of the excitation light source 53, the polarization splitting element 60, and the solid state laser medium 54, and dissipates heat generated by at least one of the excitation light source 53, the polarization splitting element 60, and the solid state laser medium 54. The cooling member 62 is, for example, a metal material such as Cu having higher thermal conductivity. The cooling member 62 may be bonded to an unillustrated package, and dissipates heat from the cooling member 62 to the package.

The support substrate 51 of the laser amplification element 50 in FIGS. 16A to 16C is, for example, a Cu substrate, and the submount substrate 52 is disposed thereon. The submount substrate 52 is, for example, a laminated structure of an SiC layer 64 and an AuSn layer 65, and p electrodes 73 and n electrodes 74 of the excitation light source 53 are electrically insulated from each other and bonded on the AuSn layer 65.

The excitation light source 53 is the laminated semiconductor layer 2 formed by laminating an n-contact layer 67, an n-DBR 68, a clad layer 69, an active layer 70, a clad layer 71, and a p-DBR 72 in order on an n-GaAs substrate 66. The p electrodes 73 and the n electrodes 74 are alternately disposed on the p-DBR 72. The p electrodes 73 conduct with the p-DBR 72, and the n electrodes 74 conduct with the n-DBR 68 via a via 75.

The laser amplification element 50 according to the present disclosure includes the first resonator 55 similarly to FIG. 1. The first resonator 55 resonates the light of the first wavelength λ1 between the first reflection layer R1 in the excitation light source 53 and the second reflection layer R2 in the solid state laser medium 54. The first reflection layer R1 is the p-DBR 72, and the second reflection layer R2 is disposed on, for example, the upper surface of a heat exhaust member 61. The heat exhaust member 61 may be omitted. The resonating operation of the light of the first wavelength λ1 performed by the first resonator 55 excites the solid state laser medium 54. FIG. 16A schematically illustrates the resonating operation of the first resonator 55 as a thin line. Amplified light (seed light) of the second wavelength λ2 is caused to be incident on the solid state laser medium 54 in the excited state in a left direction from the right end in FIG. 16A. Thus, stimulated emission of the amplified light occurs, and the amplified light is subjected to laser amplification.

Furthermore, when Yb:YAG is used as the amplification medium 83, and laser light whose wavelength is 1030 nm is used as seed light, there is a problem that the laser light is absorbed in a region that is not excited in the amplification medium 83, and cannot be sufficiently amplified. Hence, when Yb:YAG is used as the amplification medium 83, seed light that does not cause light absorption even in a non-excited state and whose wavelength is 1050 nm can be used. In this case, light absorption may not occur even in the non-excited state, and therefore the wavelength of the seed light is not limited to 1050 nm.

As described above, by providing the solid state laser medium 54 inside the first resonator 55, it is possible to substantially simplify an optical configuration, and achieve miniaturization.

Furthermore, the size of the solid state laser medium 54 in the laser amplification element 50 according to the present disclosure is not restricted by an absorption length of excitation light, so that it is possible to increase the area of the solid state laser medium 54 irrespectively of the absorption length of the excitation light. By increasing the area of the solid state laser medium 54, it is possible to further improve an amplification factor of the laser amplification element 50.

Furthermore, the excitation light source 53 constituted by the laminated semiconductor layer 2 and the solid state laser medium 54 can be integrally bonded, and the laser amplification element 50 according to the present disclosure can be manufactured by a general-purpose semiconductor process, so that it is easy to achieve miniaturization, and it is also possible to reduce manufacturing cost.

### <<Application Example>>

The technique according to the present disclosure is widely applicable to medical imaging systems (hereinafter, also referred to as electronic devices), distance measurement systems such as Light Detection And Ranging (LiDAR) devices, light sources for laser machining devices, and the like. The medical imaging systems are medical systems that use an imaging technique, and are, for example, an endoscopic system and a microscopic system.

### [Endoscopic System]

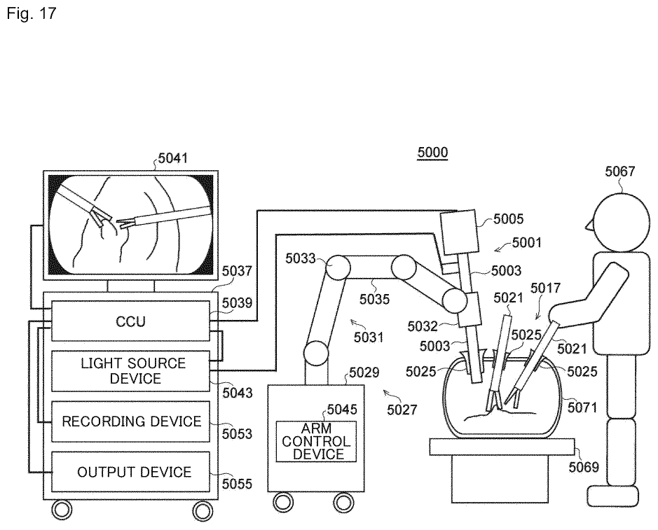

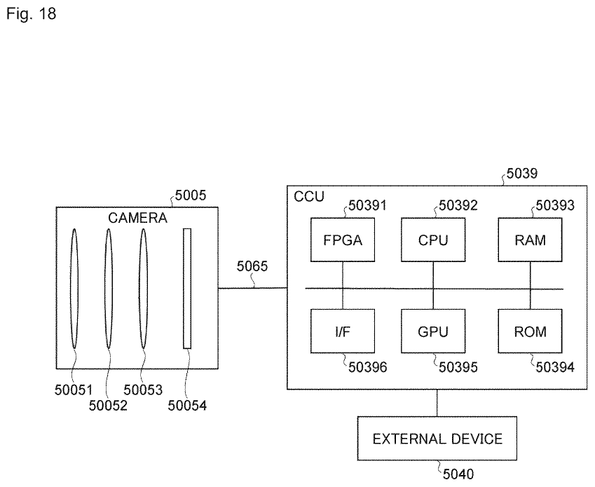

An example of the endoscopic system will be described with reference to FIGS. 17 and 18. FIG. 17 is a diagram illustrating an example of a schematic configuration of an endoscopic system 5000 to which the technique according to the present disclosure is applicable. FIG. 18 is a diagram illustrating an example of configurations of an endoscope 5001 and a Camera Control Unit (CCU) 5039. FIG. 17 illustrates a state where a surgeon (doctor) 5067 who is a surgery participant is performing a surgical operation on a patient 5071 on a patient bed 5069 by using the endoscopic system 5000. As illustrated in FIG. 17, the endoscopic system 5000 includes the endoscope 5001 that is the medical imaging device, the CCU 5039, a light source device 5043, a recording device 5053, an output device 5055, and a support device 5027 that supports the endoscope 5001.

According to an endoscopic surgical operation, an insertion auxiliary tool that is called a trocar 5025 is punctured to the patient 5071. Furthermore, a scope 5003 and a surgical tool 5021 connected to the endoscope 5001 are inserted into a body of the patient 5071 via the trocar 5025. Examples of the surgical tool 5021 are an energy device such as an electrical scalpel and a forcep.

A surgical operation image that is a medical image showing the interior of the body of the patient 5071 imaged by the endoscope 5001 is displayed on a display device 5041. The surgeon 5067 treats a surgical operation target using the surgical tool 5021 while looking at the surgical operation image displayed on the display device 5041. Note that the medical image is not limited to the surgical operation image, and may be a diagnosis image that is imaged during diagnosis.

### (Endoscope)

The endoscope 5001 is an imaging unit that images the interior of the body of the patient 5071, and is a camera 5005 that includes, for example, a condenser optical system 50051 that condenses incident light, a zoom optical system 50052 that changes a focal distance of the imaging unit and enables optical zoom, a focus optical system 50053 that changes the focal distance of the imaging unit and enables focus adjustment, and a light reception element 50054 as illustrated in FIG. 18. The endoscope 5001 generates a pixel signal by condensing the light on the light reception element 50054 via the connected scope 5003, and outputs the pixel signal to the CCU 5039 via a transmission system. Note that the scope 5003 is an insertion part that includes an objective lens at the distal end, and guides light from the connected light source device 5043 to the interior of the body of the patient 5071. The scope 5003 is, for example, a rigid scope in a case of a rigid mirror, and a flexible scope in a case of a flexible mirror. The scope 5003 may be a forward-viewing endoscope or a forward-oblique viewing endoscope. Furthermore, the pixel signal may be a signal that is based on a signal output from a pixel, and is, for example, a RAW signal or an image signal. Furthermore, a memory may be mounted on the transmission system that connects the endoscope 5001 and the CCU 5039, and the memory may be configured to store parameters related to the endoscope 5001 and the CCU 5039. The memory may be disposed, for example, at a connection portion or on a cable of the transmission system. For example, the memory of the transmission system stores parameters at a time of shipping of the endoscope 5001 or parameters that change at a time of power distribution, and an operation of the endoscope may be changed based on the parameters read from the memory. Furthermore, a set of the endoscope and the transmission system may be referred to as an endoscope. The light reception element 50054 is a sensor that converts received light into a pixel signal, and is, for example, a Complementary Metal Oxide Semiconductor (CMOS) type imaging element. The light reception element 50054 is preferably an imaging element that includes a Bayer layout and can perform color photographing. Furthermore, the light reception element 50054 is preferably an imaging element that includes the number of pixels matching a resolution of 4K (the number of horizontal pixels: 3840×the number of vertical pixels: 2160), 8K (the number of horizontal pixels: 7680×the number of vertical pixels: 4320), or square 4K (the number of horizontal pixels: 3840 or more×the number of vertical pixels: 3840 or more). The light reception element 50054 may be one sensor chip or may be a plurality of sensor chips. For example, a prism that splits incident light per predetermined wavelength band may be provided, and a different light reception element may be configured to image each wavelength band. Furthermore, a plurality of light reception elements may be provided for stereoscopic vision. Furthermore, the light reception element 50054 may be a sensor that includes an arithmetic processing circuit for image processing in a chip structure, and may be a Time of Flight (ToF) sensor. Note that the transmission system is, for example, an optical fiber cable or wireless transmission. Wireless transmission only needs to enable transmission of a pixel signal generated by the endoscope 5001, and, for example, the endoscope 5001 and the CCU 5039 may be wirelessly connected, or the endoscope 5001 and the CCU 5039 may be connected via a base station in an operating room. In this case, the endoscope 5001 may simultaneously transmit not only the pixel signal, but also information (e.g., a processing priority of the pixel signal, a synchronization signal, or the like) related to the pixel signal. Note that there may be employed a configuration where the endoscope is integrated with the scope and the camera, and the light reception element is provided at a distal end part of the scope.

### [Camera Control Unit (CCU)]

The CCU 5039 is a control device that integrally controls the connected endoscope 5001 or light source device 5043, and is, for example, an information processing device that includes an FPGA 50391, a CPU 50392, a RAM 50393, a ROM 50394, a GPU 50395, and an I/F 50396 as illustrated in FIG. 18. Furthermore, the CCU 5039 may integrally control the connected display device 5041, recording device 5053, and output device 5055. For example, the CCU 5039 controls an irradiation timing, an irradiation intensity, an irradiation light source type of the light source device 5043. Furthermore, the CCU 5039 performs image processing such as development processing (e.g., demosaic processing) or correction processing on a pixel signal output from the endoscope 5001, and outputs the processed pixel signal (e.g., image) to an external device such as the display device 5041. Furthermore, the CCU 5039 transmits a control signal to the endoscope 5001, and controls driving of the endoscope 5001. The control signal is, for example, information related to imaging conditions such as a magnification and a focal distance of the imaging unit. Note that the CCU 5039 has an image down-conversion function, and may be configured to be able to simultaneously output a high-resolution (e.g., 4K) image to the display device 5041, and a low-resolution (e.g., HD) image to the recording device 5053.

Furthermore, the CCU 5039 may be connected with an external device (e.g., a recording device, a display device, an output device, or a support device) via an IP converter that converts a signal into a predetermined communication protocol (e.g., Internet Protocol (IP)). Connection of the IP converter and the external device may be configured by a wired network, or part or entirety of a network may be constructed as a wireless network. For example, the IP converter on a CCU 5039 side has a wireless communication function, and may transmit a received video to an IP switcher or an output side IP converter via a wireless communication network such as the fifth generation mobile communication system (5G) or the sixth generation mobile communication system (6G).

### [Light Source Device]

The light source device 5043 is a device that can radiate light of a predetermined wavelength band, and includes, for example, a plurality of light sources, and a light source optical system that guides light of the plurality of light sources. The light source is, for example, a xenon lamp, a LED light source, or an LD light source. The light source device 5043 includes LED light sources that are respectively associated with, for example, the three primary colors R, G, and B, and emit white light by controlling an output intensity or an output timing of each light source. Furthermore, the light source device 5043 may include a light source that can radiate special light used for special light observation in addition to a light source that radiates normal light used for normal light observation. The special light is light of a predetermined wavelength band different from the normal light that is light for normal light observation, and is, for example, near infrared light (light whose wavelength is 760 nm or more), infrared light, blue light, and ultraviolet light. The normal light is, for example, white light or green light. According to narrow band light observation that is one type of special light observation, it is possible to image predetermined tissues such as blood vessels of a mucous surface layer with a high contrast using wavelength dependency of absorption of light in body tissues by alternately radiating blue light and green light. Furthermore, according to fluorescence observation that is one type of special light observation, by radiating excitation light for exciting a drug injected into the body tissues, receiving fluorescence emitted from the drug that is the body tissues or a target, and obtaining a fluorescent image, the surgeon can easily visually check the body tissues or the like that the surgeon has difficulty in visually checking using the normal light. For example, according to fluorescence observation that uses the infrared light, it is possible to make it possible to easily visually check the structure or an affected part of the body tissues by radiating infrared light having an excitation wavelength band to a drug such as IndoCyanine Green (ICG) injected into the body tissues, and receiving the fluorescence of the drug. Furthermore, according to fluorescence observation, a drug (e.g., 5-ALA) that is excited by special light in a blue wavelength band and emits fluorescence of a red wavelength band may be used. Note that a type of irradiation light is set to the light source device 5043 under control of the CCU 5039. The CCU 5039 may have a mode that normal light observation and special light observation are alternately performed by controlling the light source device 5043 and the endoscope 5001. At this time, information based on a pixel signal obtained by special light observation is preferably superimposed on a pixel signal obtained by normal light observation. Furthermore, special light observation may be infrared light observation for radiating infrared light and observing the depth beyond an organ front surface, or multispectral observation that utilizes hyperspectral spectroscopy. Furthermore, photodynamic therapy may be used in combination.

### [Recording Device]

The recording device 5053 is a device that records a pixel signal (e.g., image) acquired from the CCU 5039, and is, for example, a recorder. The recording device 5053 records in an HDD, an SDD, or an optical disk the image acquired from the CCU 5039. The recording device 5053 may be connected to a network in a hospital, and made accessible from a device outside an operating room. Furthermore, the recording device 5053 may have an image down-conversion function or up-conversion function.

### [Display Device]

The display device 5041 is, for example, a device that can display images, and is, for example, a display monitor. The display device 5041 displays a display image based on the pixel signal acquired from the CCU 5039. Note that the display device 5041 includes a camera and a microphone to function as an input device that enables visual line recognition, voice recognition, and instruction input using a gesture.

### [Output Device]

The output device 5055 is a device that outputs information acquired from the CCU 5039, and is, for example, a printer. The output device 5055 prints on paper a print image based on the pixel signal acquired from the CCU 5039.

### [Support Device]

The support device 5027 is an articulated arm that includes a base part 5029 including an arm control device 5045, an arm part 5031 that extends from the base part 5029, and a holding part 5032 that is attached to the distal end of the arm part 5031. The arm control device 5045 includes a processor such as a CPU, and controls driving of the arm part 5031 by operating according to a predetermined program. The support device 5027 controls parameters such as the length of each link 5035 that constitutes the arm part 5031 and a rotation angle and a torque of each joint 5033 using the arm control device 5045 to control, for example, a position and a posture of the endoscope 5001 held by the holding part 5032. Consequently, it is possible to change the endoscope 5001 to a desired position or posture, insert the scope 5003 into the patient 5071, and change an observation region in the body. The support device 5027 functions an endoscope support arm that supports the endoscope 5001 during a surgical operation. Consequently, the support device 5027 can play a role of a scopist who is an assistant holding the endoscope 5001. Furthermore, the support device 5027 may be a device that supports a microscope apparatus 5301 to be described later, and can be also referred to as a medical support arm. Note that control of the support device 5027 may be an autonomous control scheme that uses the arm control device 5045, or may be a control scheme that is controlled by the arm control device 5045 based on a user's input. For example, the control scheme may be a master/slave scheme that controls the support device 5027 that is a slave device (replica device) that is a patient cart based on a motion of a master device (primary device) that is a surgeon console at the hand of the user. Furthermore, control of the support device 5027 may be able to be remotely controlled from the outside the operating room.

An example of the endoscopic system 5000 to which the technique according to the present disclosure is applicable has been described above. For example, the technique according to the present disclosure may be applied to the microscopic system.

### (Microscopic System)

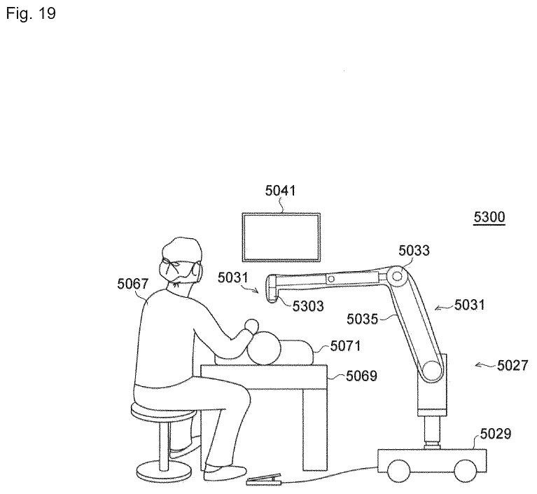

FIG. 19 is a diagram illustrating an example of a schematic configuration of a microsurgery system to which the technique according to the present disclosure is applicable. Note that, in the following description, the same components as those of the endoscopic system 5000 will be denoted by the same reference numerals and detailed description thereof will be omitted.

FIG. 19 schematically illustrates a state where the surgeon 5067 performs a surgical operation on the patient 5071 on the patient bed 5069 by using the microsurgery system 5300. Note that, in FIG. 19, for simplification, illustration of a cart 5037 of the configuration of the microsurgery system 5300 is omitted, and the microscope apparatus 5301 in place of the endoscope 5001 is simplified and illustrated. In this regard, the microscope apparatus 5301 in the description may indicate a microscope unit 5303 provided at the distal end of the link 5035, or may indicate the entire configuration including the microscope unit 5303 and the support device 5027.

As illustrated in FIG. 19, by using the microsurgery system 5300 during a surgical operation, an image of a surgical part imaged by the microscope apparatus 5301 is displayed as an enlarged image on the display device 5041 installed in the operating room. The display device 5041 is installed to face the surgeon 5067. The surgeon 5067 performs various operations such as a resection of an affected part on the surgical part while observing a state of the surgical part through a video shown on the display device 5041. The microsurgery system is used for, for example, eye surgery and brain surgery.

The example of the endoscopic system 5000 and the microsurgery system 5300 to which the technique according to the present disclosure is applicable has been described above. Note that systems to which the technique according to the present disclosure is applicable are not limited to such an example. For example, the support device 5027 can also support another observation device or another surgical tool instead of the endoscope 5001 or the microscope unit 5303 at the distal end. The other observation device may be, for example, forceps, tweezers, a pneumoperitoneum tube for pneumoperitoneum, or an energy treatment instrument for incising tissues and sealing a blood vessel by cauterization. The observation device and the surgical tools are supported by the support device, so that the positions can be fixed with higher stability and the workload of the medical staff can be lighter than in manual support by the medical staff. The technique according to the present disclosure may be applied to such a support device that supports configurations other than a microscope unit.

The technique according to the present disclosure can be suitably applied to the surgical tool 5021 in the configuration described above. More specifically, by irradiating an affected part of a patient with a laser pulse of a short pulse from the laser element 1 according to the present embodiment, it is possible to more safely and reliably treat the affected part.

The present technique can also take on the following configurations.

(1) A laser element includes:
a laminated semiconductor layer that includes a first reflection layer used for light of a first wavelength and an active layer that performs surface light emission at the first wavelength;

a second reflection layer that is disposed closer to a light emission surface side than the laminated semiconductor layer, and is used for the light of the first wavelength; and
a polarization splitting element that individually resonates and multiplexes each of orthogonal polarized beams included in light emitted from the laminated semiconductor layer between the first reflection layer and the second reflection layer.

(2) In the laser element described in (1), the laminated semiconductor layer includes a plurality of laminated semiconductor regions associated with the orthogonal polarized beams, and the polarization splitting element individually resonates and multiplexes a corresponding polarized beam between the first reflection layer and the second reflection layer for each of the plurality of laminated semiconductor regions.

(3) In the laser element described in (1) or (2), the polarization splitting element includes a first surface that is in contact with a light emission surface of the laminated semiconductor layer, and a second surface that is disposed on an opposite side to the first surface and between the first reflection layer and the second reflection layer.

(4) In the laser element described in any one of (1) to (3), the orthogonal polarized beams include orthogonal polarized beams of different wavelengths, and the polarization splitting element individually resonates and multiplexes each of the orthogonal polarized beams including the orthogonal polarized beams of the different wavelengths between the first reflection layer and the second reflection layer.

(5) In the laser element described in (4), the orthogonal polarized beams include a Transverse Magnetic (TM) polarized beam and a Transverse Electric (TE) polarized beam, and
the polarization splitting element individually resonates and multiplexes each of the TE polarized beam and the TM polarized beam between the first reflection layer and the second reflection layer.

(6) In the laser element described in (5), the polarization splitting element multiplexes the TE polarized beam with the TM polarized beam inside the polarization splitting element.

(7) In the laser element described in any one of (1) to (6), the polarization splitting element includes a laminated body obtained by alternately laminating a plurality of polarization splitting films and a plurality of reflection films with an interval spaced apart from each other,
the laminated body has a cross-sectional surface obtained by cutting the laminated body in a direction of 45 degrees in a normal direction of a lamination surface, and the polarization splitting element is disposed such that the normal direction of the cross-sectional surface is parallel to a normal direction of the laminated semiconductor layer.

(8) In the laser element described in any one of (1) to (6), the polarization splitting element includes a birefringent material for splitting the light emitted from the laminated semiconductor layer into the orthogonal polarized beams.

(9) The laser element described in any one of (1) to (8) further includes a laser medium that is disposed closer to the light emission surface side than the polarization splitting element, and resonates at a second wavelength different from the first wavelength.

(10) The laser element described in (9) includes:
a third reflection layer that is disposed on a first end surface of the laser medium on a side of the polarization splitting element, and is used for light of the second wavelength; and
a fourth reflection layer that is disposed on a second end surface of the laser medium on a side opposite to the first end surface, and is used for the light of the second wavelength.

(11) In the laser element described in (10), the third reflection layer is disposed closer to the light emission surface side than the second reflection layer.

(12) In the laser element according described in (10), the third reflection layer is disposed between the polarization splitting element and the second reflection layer.

(13) In the laser element described in (12), the third reflection layer is in contact with an end surface of the polarization splitting element.

(14) In the laser element described in any one of (10) to (13), the fourth reflection layer is in contact with the second reflection layer or disposed closer to the light emission surface side than the second reflection layer.

(15) The laser element described in (9) further includes a saturable absorber that is disposed closer to the light emission surface side than the laser medium.

(16) The laser element described in (15) further includes:
a third reflection layer that is disposed on an end surface of the laser medium on a side facing the polarization splitting element, and is used for light of the second wavelength; and
a fourth reflection layer that is disposed on the light emission surface side of the saturable absorber, and is used for the light of the second wavelength.

(17) In the laser element described in (16), the third reflection layer is disposed closer to the light emission surface side than the second reflection layer.

(18) In the laser element described in (16), the second reflection layer is disposed between the third reflection layer and the fourth reflection layer.

(19) In the laser element described in any one of (15) to (18), each of the laminated semiconductor layer, the polarization splitting element, the laser medium, and the saturable absorber is divided into a plurality of regions in association with a plurality of light emitting units that emit pulse laser light of the second wavelength disposed at a predetermined interval.

(20) An imaging device includes:
a laser element; and
a control unit that performs control to emit light from the laser element, and the laser element includes
a laminated semiconductor layer that includes a first reflection layer used for light of a first wavelength and an active layer that performs surface light emission at the first wavelength,
a second reflection layer that is disposed closer to a light emission surface side than the laminated semiconductor layer, and is used for the light of the first wavelength, and
a polarization splitting element that individually resonates and multiplexes each of a plurality of polarized beams included in light emitted from the laminated semiconductor layer between the first reflection layer and the second reflection layer.

Aspects of the present disclosure are not limited to the aforementioned individual embodiments and include various modifications that those skilled in the art can achieve, and effects of the present disclosure are also not limited to the details described above. In other words, various additions, modifications, and partial deletion can be made without departing from the conceptual idea and the gist of the present disclosure that can be derived from the details defined in the claims and the equivalents thereof.

### Reference Signs List

1, 1a, 1b, 1c, 1d, le, 1f, 1g, 1h Laser element
2 Excitation light source (laminated semiconductor layer)
2a First laminated semiconductor region
2b Second laminated semiconductor region
3 Solid state laser medium
4 Saturable absorber
5 n-GaAs substrate
6 Clad layer
7 Active layer
8 Clad layer
10 Polarization splitting element
11 First resonator
12 Second resonator
13 First optical member
14 Second optical member
15 Material layer
16 Polarization splitting film
17 Reflection film
17a First reflection film
17b Second reflection film
20 Light emission unit
21 Base material layer
22 First substrate
23 Base material layer
24 Second substrate
25 Laminated body
31 Pre-oxidation layer
32 Post-oxidation layer (e.g., Al₂O₃ layer)
33 Contact layer
34 Insulating film
35 Conductive material
50 Laser amplification element
51 Support substrate
52 Submount substrate
53 Excitation light source
54 Solid state laser medium
55 First resonator
56 First reflection member
57 Second reflection member
60 Polarization splitting element
61 Heat exhaust member
62 Cooling member
64 SiC layer
65 AuSn layer
66 n-GaAs substrate
67 Contact layer
69 Clad layer
70 Active layer
71 Clad layer
73 p electrode
74 n electrode
75 Via
83 Amplification medium
100 Laser element

1. A laser element comprising:
a laminated semiconductor layer that includes a first reflection layer used for light of a first wavelength and an active layer that performs surface light emission at the first wavelength;
a second reflection layer that is disposed closer to a light emission surface side than the laminated semiconductor layer, and is used for the light of the first wavelength; and
a polarization splitting element that individually resonates and multiplexes each of orthogonal polarized beams included in light emitted from the laminated semiconductor layer between the first reflection layer and the second reflection layer.

2. The laser element according to claim 1, wherein
the laminated semiconductor layer includes a plurality of laminated semiconductor regions associated with the orthogonal polarized beam, and
the polarization splitting element individually resonates and multiplexes a corresponding polarized beam between the first reflection layer and the second reflection layer for each of the plurality of laminated semiconductor regions.

3. The laser element according to claim 1, wherein the polarization splitting element includes a first surface that is in contact with a light emission surface of the laminated semiconductor layer, and a second surface that is disposed on an opposite side to the first surface and between the first reflection layer and the second reflection layer.

4. The laser element according to claim 1, wherein
the orthogonal polarized beams include orthogonal polarized beams of different wavelengths, and
the polarization splitting element individually resonates and multiplexes each of the orthogonal polarized beams including the orthogonal polarized beams of the different wavelengths between the first reflection layer and the second reflection layer.

5. The laser element according to claim 4, wherein
the orthogonal polarized beams include a Transverse Magnetic (TM) polarized beam and a Transverse Electric (TE) polarized beam, and
the polarization splitting element individually resonates and multiplexes each of the TE polarized beam and the TM polarized beam between the first reflection layer and the second reflection layer.

6. The laser element according to claim 5, wherein the polarization splitting element multiplexes the TE polarized beam with the TM polarized beam inside the polarization splitting element.

7. The laser element according to claim 1, wherein
the polarization splitting element includes a laminated body obtained by alternately laminating a plurality of polarization splitting films and a plurality of reflection films with an interval spaced apart from each other,
the laminated body has a cross-sectional surface obtained by cutting the laminated body in a direction of 45 degrees in a normal direction of a lamination surface, and the polarization splitting element is disposed such that the normal direction of the cross-sectional surface is parallel to a normal direction of the laminated semiconductor layer.

8. The laser element according to claim 1, wherein the polarization splitting element includes a birefringent material for splitting the light emitted from the laminated semiconductor layer into the orthogonal polarized beams.

9. The laser element according to claim 1, further comprising a laser medium that is disposed closer to the light emission surface side than the polarization splitting element, and resonates at a second wavelength different from the first wavelength.

10. The laser element according to claim 9, further comprising:
a third reflection layer that is disposed on a first end surface of the laser medium on a side of the polarization splitting element, and is used for light of the second wavelength; and
a fourth reflection layer that is disposed on a second end surface of the laser medium on a side opposite to the first end surface, and is used for the light of the second wavelength.

11. The laser element according to claim 10, wherein the third reflection layer is disposed closer to the light emission surface side than the second reflection layer.

12. The laser element according to claim 10, wherein the third reflection layer is disposed between the polarization splitting element and the second reflection layer.

13. The laser element according to claim 12, wherein the third reflection layer is in contact with an end surface of the polarization splitting element.

14. The laser element according to claim 10, wherein the fourth reflection layer is in contact with the second reflection layer or disposed closer to the light emission surface side than the second reflection layer.

15. The laser element according to claim 9, further comprising a saturable absorber that is disposed closer to the light emission surface side than the laser medium.

16. The laser element according to claim 15, further comprising:
a third reflection layer that is disposed on an end surface of the laser medium on a side facing the polarization splitting element, and is used for light of the second wavelength; and
a fourth reflection layer that is disposed on the light emission surface side of the saturable absorber, and is used for the light of the second wavelength.

17. The laser element according to claim 16, wherein the third reflection layer is disposed closer to the light emission surface side than the second reflection layer.

18. The laser element according to claim 16, wherein the second reflection layer is disposed between the third reflection layer and the fourth reflection layer.

19. The laser element according to claim 15, wherein each of the laminated semiconductor layer, the polarization splitting element, the laser medium, and the saturable absorber is divided into a plurality of regions in association with a plurality of light emitting units that emit pulse laser light of the second wavelength disposed at a predetermined interval.

20. An electronic device comprising:
a laser element; and
a control unit that performs control to emit light from the laser element, wherein the laser element includes
a laminated semiconductor layer that includes a first reflection layer used for light of a first wavelength and an active layer that performs surface light emission on the first wavelength,
a second reflection layer that is disposed closer to a light emission surface side than the laminated semiconductor layer, and is used for the light of the first wavelength, and
a polarization splitting element that individually resonates and multiplexes each of orthogonal polarized beams included in light emitted from the laminated semiconductor layer between the first reflection layer and the second reflection layer.
